(19) United States
(12) Patent Application Publication
(10) Pub. No.: US 2001/0026015 A1
(43) Pub. Date: Oct. 4, 2001

(54) Semiconductor device having reliable electrical connection

(75) Inventors: Gorou Ikegami, Tokyo (JP); Eita Iizuka, Tokyo (JP); Hirofumi Horita, Tokyo (JP)

Correspondence Address: David A. Blumenthal, FOLEY & LARDNER, Washington Harbour, 3000 K Street, N.W., Suite 500, Washington, DC, 20007-5109, US

(73) Assignee: NEC CORPORATION

(21) Appl. No.: 09/816,061

(22) Filed: Mar. 26, 2001

(30) Foreign Application Priority Data
Mar. 27, 2000 (JP) 2000-090687

(51) Int. Cl. H01L 23/053; H01L 21/44; H01L 21/48; H01L 21/50

(52) U.S. Cl. 257/701; 257/737; 257/778; 438/120

(57) ABSTRACT

A method of manufacturing a semiconductor device having reliable electrical connections between projected electrodes of a semiconductor pellet and pad electrodes of a wiring substrate. In this method, the semiconductor pellet having a plurality of projected electrodes and the wiring substrate having a plurality of pad electrodes are prepared. Liquid resin material including inorganic filler dispersed therein is applied on the wiring substrate. The semiconductor pellet is opposed to the wiring substrate via the resin material, and the projected electrodes are superposed and pressed onto the pad electrodes. The projected electrodes and the pad electrodes are electrically coupled while vibrating the resin material in the proximity of the projected electrodes and excluding the inorganic filler from superposed interface portions between the projected electrodes and the pad electrodes.

### FIELD OF THE INVENTION

The present invention relates generally to a semiconductor device in which a semiconductor pellet having projected electrodes and a wiring substrate having pad electrodes are bonded via a resin material having inorganic filler distributed therein, and a method of manufacturing such semiconductor device. More particularly, the present invention relates to a semiconductor device and method of manufacturing the same in which reliability of electrical connection between projected electrodes of a semiconductor pellet and pad electrodes of a wiring substrate can be improved.

### BACKGROUND OF THE INVENTION

It is important that electronic apparatuses, for example, a video camera, a portable personal computer and the like, are light and compact. Therefore, it is required that electronic parts or components used in such electronic apparatuses have reduced external sizes. Otherwise, even if the external sizes of the electronic parts cannot be reduced, it is possible to substantially downsize the electronic apparatuses by increasing the integration degree of the electronic parts.

FIG. 10 shows a cross sectional view of an example of a conventional semiconductor device which is used as such an electronic component. The conventional semiconductor device shown in FIG. 10 comprises a wiring substrate 104, and a semiconductor pellet 101 mounted on the wiring substrate 104. The semiconductor pellet 101 has a semiconductor substrate 102, and a plurality of projected electrodes or bump electrodes 103 formed on one of the major surfaces of the semiconductor substrate 102. In the semiconductor substrate 102, there are formed a number of semiconductor elements and/or electronic circuit elements which are internally coupled to form electronic circuit unit or units.

Each of the projected electrodes 103 is formed as follows. First, a tip portion of a wire made of gold and the like is melted to form a metal ball thereat. The metal ball is pressed and coupled onto the semiconductor substrate 102. Thereafter, the wire is pulled and cut at a middle portion thereof. In this way, a number of projected electrodes 103 are formed on the semiconductor substrate 102.

FIG. 11 is a cross sectional view of one of the projected electrodes 103 in a condition before mounting the semiconductor pellet 101 onto the wiring substrate 104. As shown in FIG. 11, the projected electrode 103 has a portion having a larger diameter, that is, a base portion 103a, and a portion having a smaller diameter, that is, a column-like portion or an elongated portion 103b. A tip portion of the column-like portion 103b has a rotated parabola shape. As an example, when a gold wire having a diameter of 30 μm is used, a diameter of the base portion 103a can be 70-100 μm, and a height thereof can be 15-25 μm. Also, in this case, a diameter of the column-like portion 103b can be approximately 30 μm, and a length thereof can be 45-55 μm. By changing the diameter of the wire used, it is possible to change the diameters of the portions 103a and 103b.

The wiring substrate 104 comprises an insulating substrate 105 which has conductor patterns formed on one of the surfaces thereof and not shown in the drawing, and pad electrodes 106 formed on portions of the conductor patterns on the insulating substrate 105. The insulating substrate 105 is made of heat-resistant material. The locations of the pad electrodes 106 correspond to the locations of the projected electrodes 103. The conductive patterns on the insulating substrate 105 are formed, for example, by etching a copper foil formed on the insulating substrate and having a thickness of 12-18 μm. The pad electrodes 106 are formed by forming, on the copper foil, a nickel plated layer having a thickness of 3-5 μm and by further forming a gold plated layer having a thickness of 0.03-1.0 μm.

The semiconductor device shown in FIG. 10 further comprises a resin material portion 107 for sealing purposes. In order to mitigate an influence caused by the difference of the thermal expansion coefficients between the semiconductor pellet 101 and the wiring substrate 104, minute inorganic filler 108 of alumina or silica having a grain size of 2-6 μm is dispersed in the resin material portion 107 at a concentration or a rate of 50-80 weight percent.

An explanation will now be made on a conventional method of manufacturing a semiconductor device having the above-mentioned structure. FIG. 12A through FIG. 12D are cross sectional views showing a conventional method of manufacturing the semiconductor device of FIG. 10 in order of manufacturing steps. First, as shown in FIG. 12A, the wiring substrate 104 are located on a flat supporting table 109. The supporting table 109 has a heater built therein and not shown in the drawing, and can heat the wiring substrate 104 according to the necessity.

As shown in FIG. 12B, liquid resin material 107a is applied on the wiring substrate 104. Then, as shown in FIG. 12C, the semiconductor pellet 101 is sucked at the bottom end of a suction collet 110 such that the projected electrodes 103 of the semiconductor pellet 101 face downward. The semiconductor pellet 101 sucked by the suction collet 110 is transferred over the supporting table 109. The suction collet 110 has a heater built therein and not shown in the drawing for heating the semiconductor pellet 101.

The location of the semiconductor pellet 101 is adjusted such that the projected electrodes 103 are located just above the corresponding pad electrodes 106 on the wiring substrate 104 covered by the liquid resin material 107a. Then, the suction collet 110 is lowered. Thereby, as shown in FIG. 12D, the projected electrodes 103 are contacted and pressed on the pad electrodes 106 within the resin material 107a, and the column-like portions 103b of the projected electrodes 103 are crushed and expand in radial directions. When the projected electrodes 103 are superposed and pressed onto the pad electrodes 106, the liquid resin material 107a is simultaneously pushed toward the periphery of the semiconductor pellet 101. The liquid resin material 107a covers the surface of the semiconductor pellet 101 on which the pad electrodes are formed and covers coupling portions between the projected electrodes 103 and the pad electrodes 106.

Further, while keeping the semiconductor pellet 101 pressed onto the wiring substrate 104, the semiconductor pellet 101 is heated by the heater within the suction collet 110, and the wiring substrate 104 is heated by the heater within the supporting table 109. Thereby, the wiring substrate 104 is heated to 80-100 degrees Celsius and the semiconductor pellet 101 is heated to 270-300 degrees Celsius, while exerting load of 0.294-0.49N (30-50 gf) for 10-60 seconds onto each of the projected electrodes 103. Thereby, the projected electrodes 103 and the pad electrodes 106 are electrically coupled by thermo compression bonding.

In this case, by the heat provided via the semiconductor pellet 101 and the wiring substrate 104, the resin material 107a is also heated and cured. By the cured resin material portion 107, the semiconductor pellet 101 is joined with the wiring substrate 104, and coupling portions between the projected electrodes 103 and the pad electrodes 106 together with the wiring layer not shown in the drawing on the surface of the semiconductor pellet 101 are protected. In this way, the semiconductor device shown in FIG. 10 is fabricated.

Technology relating to the above-mentioned semiconductor device is disclosed in Japanese patent laid-open publication No. 60-262430 (prior art 1), Japanese patent laid-open publication No. 9-97816 (prior art 2), and the like.

In general, it is required that manufacturing costs of electronic parts are reduced as well as sizes and weight thereof are decreased. Therefore, it is also important to shorten a manufacturing time of each electronic part. However, in the above-mentioned conventional manufacturing method illustrated in FIG. 12A through FIG. 12D, curing time of the resin material becomes relatively long.

Also, in the above-mentioned prior art 1 and prior art 2, the projected electrodes and the pad electrodes are electrically coupled by pressure welding or compression welding, and compressed condition is maintained by the bonding force of the resin material. Thus, it is impossible to release pressuring of the semiconductor pellet until the resin material cures completely.

Therefore, in general, the resin material having a short curing time is used. However, if pressuring and heating of the semiconductor pellet are released in the condition the resin material is not yet cured completely, the following disadvantages arise. That is, since the quantity of contraction of the electrodes is larger than that of the resin material, the electrical coupling between the projected electrodes and the pad electrodes becomes unstable. Therefore, in practice, it is impossible to release the pressuring of the semiconductor pellet until the resin material cures sufficiently, and it is impossible to reduce processing time.

In order to reduce manufacturing time of the semiconductor device, it may be possible to heat the resin material early. In such case, viscosity of the resin material decreases first, and, after reaching the lowest value, the viscosity of the resin material increases and curing of the resin material progresses. Therefore, there is a possibility that the resin material remains between the projected electrodes and the pad electrodes and that the electrical coupling therebetween becomes unstable. Also, the electrical resistance between the projected electrodes and the pad electrodes varies.

On the other hand, a technology is known in which projected electrodes and pad electrodes are ultrasonic bonded. Such technology is disclosed, for example, in Japanese patent laid-open publication No. 10-335373 (prior art 3).

In the technology of the Japanese patent laid-open publication No. 10-335373, resin material is previously supplied on a wiring substrate and the wiring substrate is heated. A suction collet for sucking a semiconductor pellet is attached to a tip portion of a horn for transmitting ultrasonic vibration. The semiconductor pellet is heated and pressed by the suction collet and ultrasonic vibration is applied simultaneously. Thereby, the projected electrodes and the pad electrodes are coupled. Even if the resin material is in a semi-cured condition, the semiconductor device can be transferred soon after the coupling between the projected electrodes and the pad electrodes are finished. Therefore, it is possible to reduce the manufacturing time of the semiconductor device.

In the semiconductor device shown in FIG. 10, in order to downsize and thin down the semiconductor device, a resin substrate is generally used as the wiring substrate 104. In such case, a thermal expansion coefficient of the semiconductor pellet 101 and that of the wiring substrate 104 differ from each other greatly. Therefore, during operation of the semiconductor device, the wiring substrate 104 which has a larger thermal expansion coefficient than that of the semiconductor pellet 101 warps largely due to the heat generated by the semiconductor pellet 101. As a result thereof, there is a possibility that a stress concentrates in the coupling portion between the projected electrodes and the pad electrodes and, thereby, a reliability of the coupling portion is deteriorated.

To avoid such disadvantage, it is possible to disperse a large amount of inorganic powder filler 108 such as alumina, silica and the like which has a thermal expansion coefficient close to that of the semiconductor pellet 101 in the resin material 107a. Thereby, the thermal expansion coefficient of the resin material 107a in which the inorganic filler 108 is dispersed can be a medium value between the thermal expansion coefficient of the semiconductor pellet 101 and that of the wiring substrate 104. Since the stress caused at the coupling portion between the projected electrodes and the pad electrodes is mitigated, it is possible to avoid delamination of the coupling portion between the projected electrodes and the pad electrodes.

As mentioned above, in the semiconductor device shown in FIG. 10, the resin substrate is used as the wiring substrate 104, and a large quantity of inorganic filler 108 is dispersed in the resin material 107 for bonding. Therefore, the inorganic filler 108 is also disposed densely between the projected electrodes 103 and the pad electrodes 106. When the projected electrodes 103 are superposed on the pad electrodes 106, the inorganic filler 108 is also put into the interface between the projected electrodes 103 and the pad electrodes 106 with high probability.

When a large amount of inorganic filler 108 which is an insulator is put into the interface between the projected electrodes 103 and the pad electrodes 106, a cross sectional area of conducting portions of each of the minute projected electrodes 103 is decreased and coupling resistance between each of the projected electrodes 103 and corresponding one of the pad electrodes 106 becomes large. This may give a bad influence on the electrical characteristics of a semiconductor device.

The above-mentioned problems become prominent when each of the projected electrodes is downsized and a cross sectional area of each of the projected electrodes is decreased according to an increase in the number of electrodes. The above-mentioned problems occur in the prior art 3 in which the projected electrodes and the pad electrodes are ultrasonic bonded, as well as in the prior arts 1 and 2 in which the projected electrodes are pressed onto the pad electrodes and the pad electrodes and the pad electrodes are heated for thermo compression bonding. It was impossible to remove the inorganic filler remaining in the interface portions between the projected electrodes and the pad electrodes. Therefore, a manufacturing yield of a semiconductor device is deteriorated and manufacturing costs thereof become high.

### SUMMARY OF THE INVENTION

Therefore, it is an object of the present invention to provide a semiconductor device and a method of manufacturing the same in which the above-mentioned problems of the conventional technology are obviated.

It is another object of the present invention to provide a semiconductor device and a method of manufacturing the same in which electrodes of a semiconductor pellet and electrodes of a wiring substrate are surely coupled with each other.

It is still another object of the present invention to provide a semiconductor device and a method of manufacturing the same in which electrical resistance between electrodes of a semiconductor pellet and electrodes of a wiring substrate can be reduced.

It is still another object of the present invention to provide a semiconductor device and a method of manufacturing the same in which reliability of electrical coupling between electrodes of a semiconductor pellet and electrodes of a wiring substrate can be improved.

It is still another object of the present invention to provide a semiconductor device which has stable electrical characteristics, and a method of manufacturing such semiconductor device.

It is still another object of the present invention to provide a semiconductor device and a method of manufacturing the same in which the semiconductor device can be downsized and thinned down and the number of electrodes can be increased, without deteriorating reliability thereof.

It is still another object of the present invention to provide a semiconductor device and a method of manufacturing the same in which manufacturing costs of the semiconductor device can be decreased.

According to an aspect of the present invention, there is provided a method of manufacturing a semiconductor device comprising: preparing a semiconductor pellet having a plurality of projected electrodes; preparing a wiring substrate having a plurality of pad electrodes; applying liquid resin material including inorganic filler dispersed therein on the wiring substrate; opposing the semiconductor pellet to the wiring substrate via the resin material, and electrically coupling the projected electrodes and the pad electrodes by superposing and pressing the projected electrodes onto the pad electrodes, the projected electrodes and the pad electrodes being electrically coupled while vibrating the resin material in the proximity of the projected electrodes and excluding the inorganic filler from superposed interface portions between the projected electrodes and the pad electrodes; and curing the resin material to join the semiconductor pellet and the wiring substrate.

In this case, it is preferable that an end portion of each of the projected electrodes has a cross section which becomes smaller toward the tip portion thereof.

It is also preferable that the resin material in the proximity of the projected electrodes is vibrated by applying ultrasonic vibration to the semiconductor pellet or to the wiring substrate.

It is further preferable that, in the opposing the semiconductor pellet to the wiring substrate via the resin material, and electrically coupling the projected electrodes and the pad electrodes by superposing and pressing the projected electrodes onto the pad electrodes, the projected electrodes are pressed onto the pad electrodes such that the projected electrodes are elastically deformed, and application of the ultrasonic vibration is started in a condition the projected electrodes are elastically deformed.

It is advantageous that, by starting the application of the ultrasonic vibration in a condition the projected electrodes are elastically deformed, an area of contact of each of the projected electrodes with corresponding one of the pad electrodes rapidly enlarges.

It is also advantageous that an output of the ultrasonic vibration is 20-100 mW per one projected electrode.

It is further advantageous that an application time of the ultrasonic vibration is 0.1-5 seconds.

It is preferable that the projected electrodes and the pad electrodes are ultrasonic bonded.

It is also preferable that, in the in the opposing the semiconductor pellet to the wiring substrate via the resin material, and electrically coupling the projected electrodes and the pad electrodes by superposing and pressing the projected electrodes onto the pad electrodes, the projected electrodes and the pad electrodes are thermo compression bonded by pressing the projected electrodes onto the pad electrodes while heating the semiconductor pellet.

It is further preferable that, before vibrating the resin material in the proximity of the projected electrodes, the resin material is heated to lower viscosity of the resin material.

It is advantageous that the inorganic filler comprises minute powder of alumina or silica.

According to another aspect of the present invention, there is provided a semiconductor device comprising: a wiring substrate having a plurality of pad electrodes; a semiconductor pellet having a plurality of projected electrodes and opposed to the wiring substrate, the projected electrodes of the semiconductor pellet being electrically coupled with the pad electrodes of the wiring substrate, respectively; and a resin material portion filling a space between the semiconductor pellet and the wiring substrate and joining the semiconductor pellet and the wiring substrate, the resin material including inorganic filler dispersed therein; wherein the inorganic filler hardly exists in superposed interface portions between the projected electrodes and the pad electrodes, and a dispersion rate of the inorganic filler in the resin material is larger in portions near and around the superposed interface portions than in other portions of the resin material.

According to still another aspect of the present invention, there is provided a method of manufacturing a semiconductor device comprising: preparing a semiconductor pellet having a plurality of projected electrodes; preparing a wiring substrate having a plurality of pad electrodes; applying liquid resin material including inorganic filler dispersed therein on the wiring substrate; opposing the semiconductor pellet to the wiring substrate via the resin material, and superposing and pressing the projected electrodes onto the pad electrodes, the projected electrodes being pressed onto the pad electrodes such that the projected electrodes are elastically deformed; applying ultrasonic vibration to the semiconductor pellet and/or the wiring substrate in a condition the projected electrodes are pressed onto the pad electrodes such that the projected electrodes are elastically deformed, and electrically coupling the projected electrodes and the pad electrodes; and curing the resin material to join the semiconductor pellet and the wiring substrate.

In this case, it is preferable that an end portion of each of the projected electrodes has a cross section which becomes smaller toward the tip portion thereof.

It is also preferable that, in the applying ultrasonic vibration to the semiconductor pellet and/or the wiring substrate in a condition the projected electrodes are pressed onto the pad electrodes such that the projected electrodes are elastically deformed, and electrically coupling the projected electrodes and the pad electrodes, the projected electrodes expand in radial directions and are compressed in axial direction by applying the ultrasonic vibration to the semiconductor pellet, the projected electrodes and the pad electrodes being electrically coupled while excluding the inorganic filler from superposed interface portions between the projected electrodes and the pad electrodes.

It is further preferable that, in the applying ultrasonic vibration to the semiconductor pellet and/or the wiring substrate in a condition the projected electrodes are pressed onto the pad electrodes such that the projected electrodes are elastically deformed, and electrically coupling the projected electrodes and the pad electrodes, an area of contact of each of the projected electrodes with corresponding one of the pad electrodes is rapidly enlarged by applying the ultrasonic vibration to the semiconductor pellet, the projected electrodes and the pad electrodes being electrically coupled while excluding the inorganic filler from superposed interface portions between the projected electrodes and the pad electrodes.

It is advantageous that an output of the ultrasonic vibration is 20-100 mW per one projected electrode.

It is also advantageous that an application time of the ultrasonic vibration is 0.1-5 seconds.

It is further advantageous that, before applying the ultrasonic vibration, the resin material is heated to lower viscosity of the resin material.

It is advantageous that the inorganic filler comprises minute powder of alumina or silica.

### BRIEF DESCRIPTION OF THE DRAWINGS

These and other features, and advantages, of the present invention will be more clearly understood from the following detailed description taken in conjunction with the accompanying drawings, in which like reference numerals designate identical or corresponding parts throughout the figures, and in which:

FIG. 1 is a schematic cross sectional view of a semiconductor device according to an embodiment of the present invention;

FIG. 2 is a partial enlarged cross sectional view of the semiconductor device of FIG. 1;

FIG. 3 is a schematic cross sectional view illustrating a structure of a semiconductor pellet during a manufacturing process of a semiconductor device according to an embodiment of the present invention;

FIG. 4 is a schematic cross sectional view illustrating a structure of a wiring substrate during a manufacturing process of a semiconductor device according to an embodiment of the present invention;

FIG. 5 is a schematic cross sectional view illustrating a structure including a liquid resin portion applied on a wiring substrate during a manufacturing process of a semiconductor device according to an embodiment of the present invention;

FIG. 6 is a schematic cross sectional view illustrating a structure including a semiconductor pellet and a wiring substrate during a manufacturing process of a semiconductor device according to an embodiment of the present invention;

FIG. 7 is a graph showing relationships of heights of a semiconductor pellet and load exerted on the semiconductor pellet with respect to time;

FIG. 8 is a partial enlarged cross sectional view which shows a cross sectional structure in the vicinity of a projected electrode and a pad electrode and which shows a condition immediately after the projected electrode contacts the pad electrode;

FIG. 9 is a partial enlarged cross sectional view showing a condition in the vicinity of the projected electrode and the pad electrode just after applying ultrasonic vibration;

FIG. 10 shows a cross sectional view of an example of a conventional semiconductor device;

FIG. 11 is a cross sectional view of a projected electrode in the condition before mounting a semiconductor pellet onto the wiring substrate; and

FIG. 12A through FIG. 12D are cross sectional views illustrating a conventional method of manufacturing a semiconductor device in order of manufacturing steps.

### DESCRIPTION OF A PREFERRED EMBODIMENT

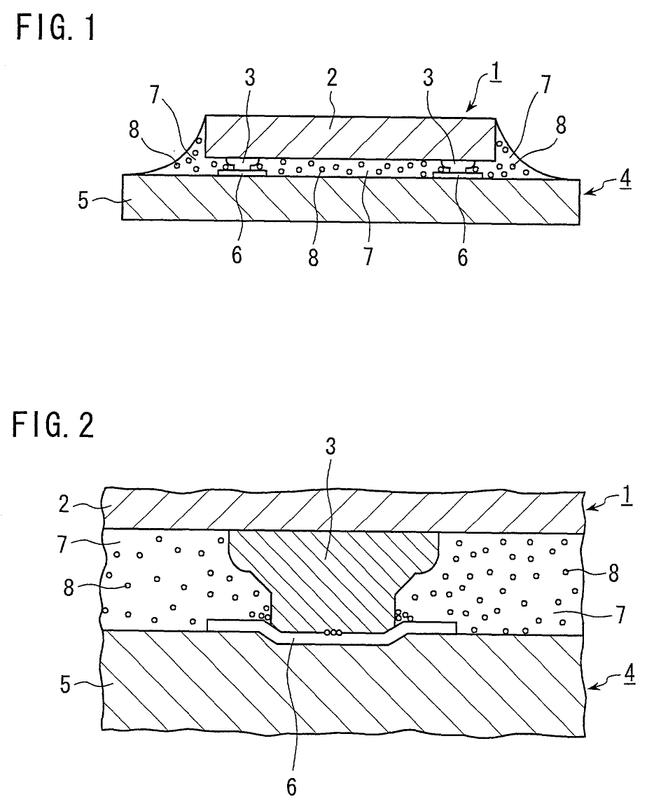

With reference to the drawings, embodiments of the present invention will now be described in detail. FIG. 1 is a schematic cross sectional view of a semiconductor device according to an embodiment of the present invention. FIG. 2 is a partial enlarged cross sectional view of FIG. 1.

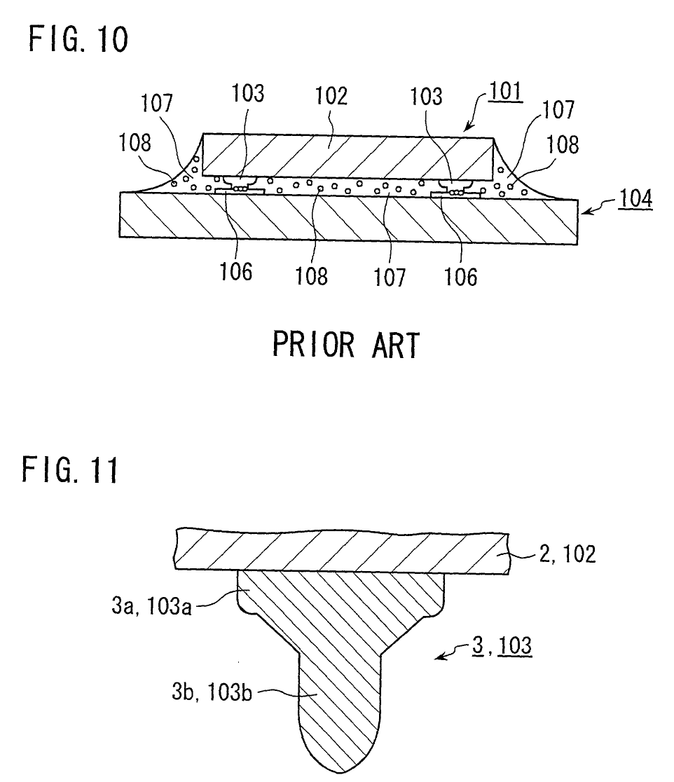

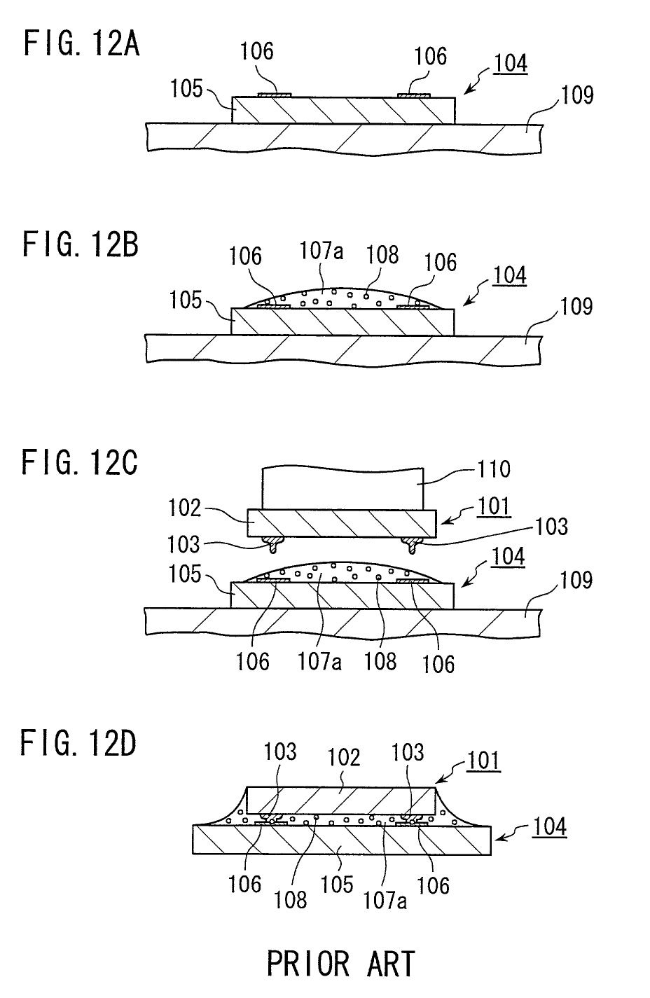

The semiconductor device shown in FIG. 1 comprises a wiring substrate 4, and a semiconductor pellet 1 mounted on the wiring substrate 4, similarly to the semiconductor device of FIG. 10. The semiconductor pellet 1 has a semiconductor substrate 2, and a plurality of projected electrodes 3 formed on one of the major surfaces of the semiconductor substrate 2. In the semiconductor substrate 2, there are formed a number of semiconductor elements or electronic circuit elements which are not shown in the drawing and which are wired internally to form an electronic circuit device. In this embodiment, as shown in the cross sectional view of FIG. 11, the projected electrodes 3 have approximately similar shape to that of the projected electrodes 103 mentioned above. The wiring substrate 4 comprises an insulating substrate 5. On one of the surface of the insulating substrate 5, there are formed conductive patterns not shown in the drawing, and, on portions of the conductive patterns, there are formed pad electrodes 6. The locations of the pad electrodes 6 correspond to the locations of the projected electrodes 3.

The semiconductor device of FIG. 1 further comprises a resin material portion 7 which fills a space between the semiconductor pellet 1 and the wiring substrate 4. The resin material portion 7 bonds or joins the semiconductor pellet 1 and the wiring substrate 4, and protects coupling portions between the projected electrodes 3 and the pad electrodes 6, the conductive patterns on the wiring substrate 4 not shown in the drawing, and the like.

Thermal expansion coefficient of the semiconductor pellet 1 and that of the wiring substrate 4 differ from each other considerably. Therefore, there is a possibility that, due to the heat generated by the semiconductor pellet 1 during operation of the semiconductor device, the wiring substrate 4 warps and stress concentrates in the coupling portions between the projected electrodes 3 and the pad electrodes 6. In order to avoid such disadvantage, inorganic filler 8 is dispersed in the resin material portion 7. The inorganic filler 8 can be made of a material having a thermal expansion coefficient close to that of the semiconductor pellet 1, for example, can be made of alumina, silica or the like. The thermal expansion coefficient of the resin material portion 7 in which the inorganic filler 8 is dispersed becomes a medium value between the thermal expansion coefficient of the semiconductor pellet 1 and that of the wiring substrate 4. Thereby, the stress exerted on the coupling portions between the projected electrodes 3 and the pad electrodes 6 can be mitigated and it becomes possible to avoid delamination at the coupling portions between the projected electrodes 3 and the pad electrodes 6.

In the semiconductor device of FIG. 1, the semiconductor pellet 1 and the wiring substrate 4 are opposed and joined by the cured resin material portion 7. Within the resin material portion 7, the projected electrodes 3 and pad electrodes 6 are superposed and electrically coupled with each other.

The characteristic features of the semiconductor device according to this embodiment are as follows. That is, when the projected electrodes 3 and the pad electrodes 6 are superposed, the inorganic filler 8 existing within the resin material 7 between the projected electrodes 3 and the pad electrodes 6 can be removed sufficiently from the superposed interface portion between the projected electrodes 3 and the pad electrodes 6, as shown in FIG. 2. As also shown in FIG. 2, the inorganic filler 8 is disposed at high concentration around and near the outside of the interface portion between each of the projected electrodes 3 and the corresponding one of the pad electrodes 6.

In a process of superposing the projected electrodes 3 on the pad electrodes 6, when tip portions of the projected electrodes 3 which are inserted into the resin material touch the pad electrodes 6, some amount of inorganic filler 8 is caught between each tip portion of the projected electrodes 3 and corresponding one of the pad electrodes. When the semiconductor pellet 1 is pressed onto the wiring substrate 4 such that the projected electrodes 3 are pressed onto the pad electrodes 6, pressure concentrates in the projected central portions of the projected electrodes 3, in particular on the tip portions of the projected electrodes 3 each having a rotated parabola shape as shown in FIG. 11. Thereby, the area of each of the superposed portions between the projected electrodes 3 and the pad electrodes 6 becomes large, and the projected electrodes 3 expand radially. When the rate of enlargement of each of the superposed areas between the projected electrodes 3 and the pad electrodes 6 and the rate of radial expansion of the peripheral wall of each of the projected electrodes 3 are appropriate, the inorganic filler 8 existing near the interface portion between the projected electrodes 3 and the pad electrodes 6 is excluded therefrom and is not caught in the interface portions between the projected electrodes 3 and the pad electrodes 6.

To compare with the semiconductor device according to the present invention, the semiconductor device fabricated by the conventional method mentioned above was carefully inspected. Minute inorganic filler having a grain size of, for example, 2-6 μm is dispersed in the resin material by 50-80 weight percent and such resin material is applied on the wiring substrate. Then, the semiconductor pellet is pressed onto the wiring substrate and heated to thermo compression bond between the projected electrodes and the pad electrodes. In such case, it was confirmed that the inorganic filler disperses and remains in an area of 10 percent or more of the area of each of the superposed interface portions between the projected electrodes and the pad electrodes. Also, it was confirmed that, within the area in which the inorganic filler remains, total area occupied by the inorganic filler itself becomes approximately 10 percent of the area in which the inorganic filler remains.

On the other hand, in the semiconductor device according to the present invention, even if the same resin material mentioned above is used, only several pieces of inorganic filler remain within an area which is 4 percent or less of the superposed interface area between each of the projected electrodes and the corresponding one of the pad electrodes. The inorganic filler hardly remain in the peripheral portion within each of the superposed interface portions between the projected electrodes and the pad electrodes.

As the size of each of the projected electrodes 3 is decreased to downsize the semiconductor device or to increase the number of electrodes, the relative area of each of the superposed interface portion with respect to the size of the inorganic filler 8 becomes small. Even in such case, in the semiconductor device according to the present embodiment, the inorganic filler 8 is removed sufficiently from the superposed interface portions between the projected electrodes 3 and the pad electrodes 6, so that it is possible to maximize an effective electrical conduction area of each of the projected electrodes 3 and to lower electrical resistance between the projected electrodes 3 and the pad electrodes 6. Therefore, it is possible to realize a semiconductor device having stable electrical characteristics.

Also, as shown in FIG. 2, in the semiconductor device according to the present embodiment, concentration or dispersion rate of the inorganic filler 8 around and near the outside portion of the interface portion between each of the projected electrodes 3 and the corresponding one of the pad electrodes 6 is larger than that of the inorganic filler 8 in other portion of the resin material portion 7. That is, concentration of the resin material itself in the proximity of coupling portions between the projected electrodes 3 and the pad electrodes 6 is relatively small. Therefore, in the proximity of the coupling portions between the projected electrodes 3 and the pad electrodes 6, penetration of moisture is inhibited by the inorganic filler 8 and it is possible to avoid moisture from penetrating into the coupling portions between the projected electrodes 3 and the pad electrodes 6. Thus, it is possible to improve moisture resistance and reliability of a semiconductor device. Also, since the inorganic filler 8 having a thermal expansion coefficient close to that of the projected electrodes 3 exists around and near the outside portions of the coupling portions between the projected electrodes 3 and the pad electrodes 6 with high concentration, it is possible to effectively mitigate the stress caused by the raise and fall of temperature at the coupling portion between the projected electrodes 3 and the pad electrodes 6. Thereby, reliability of electrical connection between the projected electrodes 3 and the pad electrodes 6 can be improved.

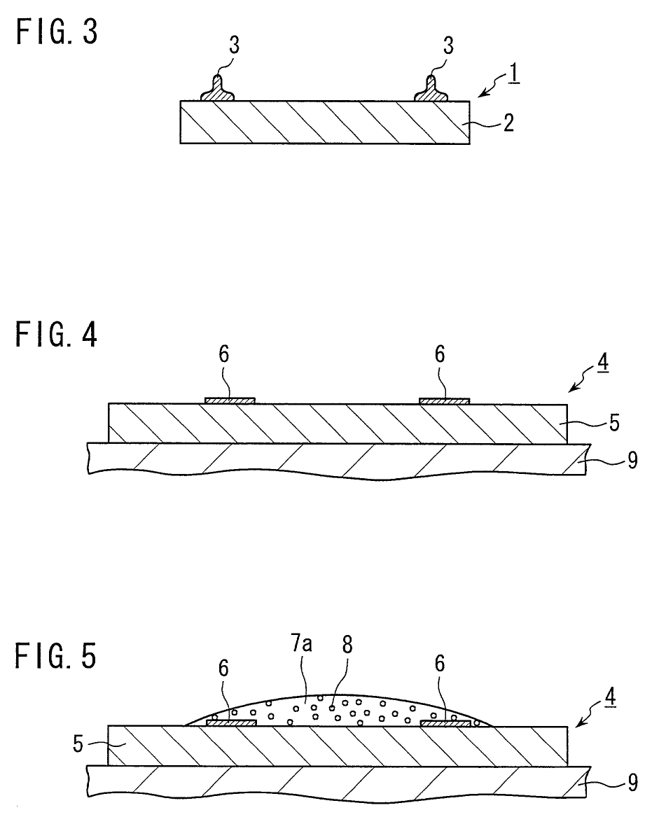

With reference to FIG. 3 through FIG. 9, an explanation will be made on a method of manufacturing a semiconductor device according to the present embodiment. First, as shown in the cross sectional view of FIG. 3, a semiconductor pellet 1 is prepared which has projected electrodes 3 formed on one of the major surfaces thereof. The projected electrodes 3 of the semiconductor pellet 1 can be formed by using, for example, plating, compression bonding of metal balls, and the like. In this embodiment, as shown in FIG. 11, the projected electrodes 3 have similar shape to that of the above-mentioned projected electrodes 103, and can be fabricated in a manner similar to the method mentioned above. For example, the projected electrodes 3 can be fabricated by compression bonding gold balls formed at tip portions of gold wires to the semiconductor pellet 1 and thereafter pulling up the wires. As shown in FIG. 11, the projected electrode 3 fabricated in this way has a portion having a larger diameter, that is, a base portion 3a, and a portion having a smaller diameter, that is, a column-like portion or an elongated portion 3b. The tip portion of the column-like portion 3b has a rotated parabola shape. As an example, when a gold wire having a diameter of 30 μm is used, a diameter of the base portion 3a can be 80-100 μm, and a height thereof can be 15-25 μm. Also, in this case, a diameter of the column-like portion 3b can be approximately 30 μm, and a length thereof can be 45-55 μm. When a gold wire having a diameter of 20 μm is used, the diameter of the base portion 3a can be approximately 70 μm.

In the semiconductor pellet 1 of 10 mm square (10 mm×10 mm), it is possible to form, for example, 215 projected electrodes 3 in the peripheral portion on the surface of the semiconductor pellet 1. In the semiconductor pellet 1 of 7 mm square (7 mm×7 mm), it is possible to form, for example, 208 projected electrodes 3.

The wiring substrate 4 as shown in the cross sectional view of FIG. 4 is prepared. The insulating substrate 5 constituting the wiring substrate 4 can be made by using a glass epoxy substrate, a resin substrate having heat resistance and electrical insulation such as a polyimide substrate and the like, or a ceramic substrate. In this embodiment, a resin substrate is used to reduce size, weight and thickness of the semiconductor device.

The pad electrodes 6 are formed on the insulating substrate 5, for example, as follows. Copper foil patterns are formed on the insulating substrate 5, for example, by etching a copper foil having a thickness of 12-18 μm formed on the insulating substrate 5. Square shaped land areas each having 100 μm square are exposed from the copper foil patterns through a resist layer formed on the copper foil patterns and the insulating substrate 5. On the square shaped land areas of the copper foil patterns, a nickel plated layer having a thickness of 3-5 μm and a gold plated layer having a thickness of 0.03-1.0 μm are sequentially formed. Thereby, the pad electrodes 6 are formed in correspondence to the locations of the projected electrodes 103 of the semiconductor pellet 1.

Then, as shown in FIG. 4, the wiring substrate 4 is located on a flat supporting table 9 such that the pad electrodes 6 face upward. The supporting table 9 has a heater built therein and not shown in the drawing.

As shown in the cross sectional view FIG. 5, a liquid resin material 7a is applied onto the wiring substrate 4. When the wiring substrate 4 is formed of a resin substrate, thermosetting resin of epoxy system and the like is used as base material of the resin material 7a, and minute inorganic filler 8 is dispersed in the resin material 7a at a concentration of 50-80 weight percent, taking thermal expansion coefficients of the semiconductor pellet 1 and wiring substrate 4 into consideration. The inorganic filler 8 is made, for example, of alumina or silica. Grain size of the inorganic filler 8 is, for example, 2-6 μm. The resin material 7a is applied such that an area including the pad electrodes 6 on the wiring substrate 4 is covered thereby. As will be mentioned later, after the semiconductor pellet 1 is mounted on the wiring substrate 4, the resin material 7a is cured and becomes the resin material portion 7 in the semiconductor device shown in FIG. 1.

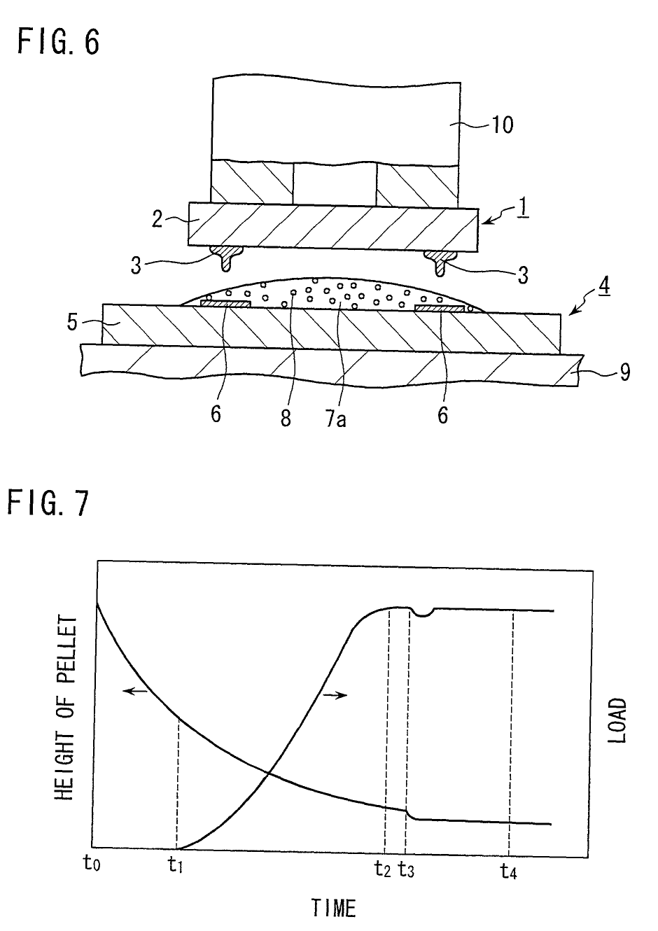

Thereafter, as shown in the cross sectional view of FIG. 6, the semiconductor pellet 1 is sucked at the bottom end of a suction collet 10 such that the projected electrodes 103 face downward. The suction collet 10 is coupled to an end portion of an ultrasonic horn not shown in the drawing, thereby it is possible to apply ultrasonic vibration to the semiconductor pellet 1.

When the semiconductor pellet 1 sucked by the suction collet 10 is transferred in a horizontal direction, location of the projected electrodes 3 is sensed by image recognition. Thereby, the location of the semiconductor pellet 1 relative to the wiring substrate 4 is adjusted such that the projected electrodes 3 are precisely located just above the corresponding pad electrodes 6 of the wiring substrate 4 fixed to the supporting table 9.

In this way, the projected electrodes 3 and the pad electrodes 6 are located such that it is possible to superpose both electrodes, and the suction collet 10 is lowered while heating the resin material 7a via the wiring substrate 4 at a temperature of 80-120 degrees Celsius. Thereby, the tip portions of the projected electrodes 3 are inserted into the resin material 7a and superposed onto the pad electrodes 6.

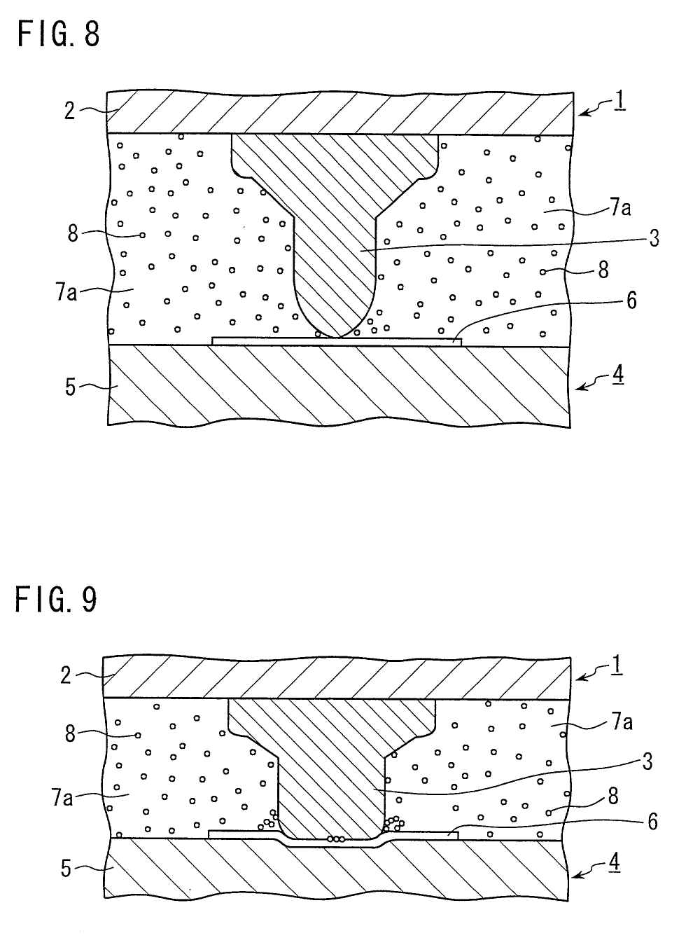

FIG. 7 is a graph showing heights of the semiconductor pellet 1 and load exerted on the semiconductor pellet 1 with respect time. An abscissa of the graph shows time, and an ordinate of the graph shows heights of the semiconductor pellet 1 and load exerted on the semiconductor pellet 1 by using arbitrary unit. As shown in FIG. 7, at time t0, the descent of the semiconductor pellet 1 is started. At time t1, a projected electrode 3 contacts a pad electrode 6. FIG. 8 is a partial enlarged cross sectional view which shows a cross sectional structure in the vicinity of the projected electrode 3 and the pad electrode 6 and which shows a condition just after the projected electrode 3 contacts the pad electrode 6 at time t1.

After contacting the pad electrode 6, the projected electrode 3 is pressed by the suction collet 10. The pressing force the suction collet 10 presses the semiconductor pellet 1 is detected by a load cell not shown in the drawing and is controlled to become a predetermined value.

In this embodiment, the semiconductor pellet 1 is pressed such that the pressing force per one projected electrode 3 becomes, for example, 0.196-0.392N (20-40 gf). By pressing the semiconductor pellet 1 in this way, each of the tip portions of the projected electrodes 3 having a rotated parabola shape is crushed and the area of contact between the projected electrode 3 and the pad electrode 6 becomes large. The column shaped portion of the projected electrode 3 is compressed in the axial direction and resiliently or elastically deformed. However, it hardly expand in radial directions. Therefore, the projected electrode 3 does not deform much.

That is, in the graph of FIG. 7, from time t1 to time t2, the column like portion 3b of the projected electrode 3 is compressed in the axial direction, and during this period the semiconductor pellet 1 gradually falls. After the time t2, the load becomes constant and the semiconductor pellet 1 stops falling.

In the condition the pressing force of the semiconductor pellet 1 is kept constant and the projected electrode 3 is elastically deformed, ultrasonic vibration is applied to the semiconductor pellet 1 via the suction collet 10. In this case, strength or output power of the ultrasonic vibration is, for example, 20-100 mW per one projected electrode 3 and the ultrasonic vibration is applied for 0.1-5 seconds.

The peripheral surface of the column like portion 3b which is compressed and elastically deformed expands instantaneously in radial directions when the ultrasonic vibration is applied. FIG. 9 is a partial enlarged cross sectional view showing a condition in the vicinity of the projected electrode 3 and the pad electrode 6 just after applying ultrasonic vibration. As shown in FIG. 9, the area of the superposed interface portion of the projected electrode 3 becomes large and the projected electrode 3 is electrically coupled with the pad electrode 6. In this case, viscosity of the resin material 7a in the vicinity of the projected electrode 3 which vibrates due to the application of the ultrasonic vibration is lowered. Therefore, the inorganic filler 8 dispersed in the resin material 7a near the projected electrode 3 becomes easily movable. Thus, the inorganic filler 8 in the resin material 7a existing between the tip portion of the projected electrode 3 having a rotated parabola shape and the pad electrode 6, together with the resin material 7a, is pushed outward from the space between the projected electrode 3 and the pad electrode 6.

In the graph of FIG. 7, the ultrasonic vibration is applied from time t3 to time t4. As shown in FIG. 7, due to the application of the ultrasonic vibration, load on the semiconductor pellet 1 varies largely just after time t3, but the load again becomes constant thereafter. Also, the height of the semiconductor pellet 1 varies rapidly for a short time just after time t3, but the height again becomes constant thereafter. The rapid change of the height of the semiconductor pellet 1 is caused by a rapid expansion of the diameter of the column portion 3b from approximately 30 μm to approximately 50 μm. In response to the rapid change of the height, the pressure between the projected electrode 3 and the pad electrode 6 also rises rapidly. Therefore, the resin material 7a existing between the projected electrode 3 and the pad electrode 6 is compressed, and it is possible to exclude the inorganic filler 8 from the superposed interface portion between the projected electrode 3 and pad electrode 6.

In this case, even if a small amount of resin material 7a and inorganic filler 8 remain in the superposed interface portion between the projected electrode 3 and the pad electrode 6, the ultrasonic vibration is applied from both sides of the resin material 7a and the inorganic filler 8, that is, from the projected electrodes 3 and the pad electrodes 6, at a relatively small energy and for a relatively long time. Therefore, the superposed surface portions between the projected electrodes 3 and the pad electrodes 6 further enlarges and the remained resin material 7a and the inorganic filler 8 can be excluded from the superposed interface portion between the projected electrode 3 and the pad electrode 6. Thereafter, the resin material 7a is cured and the semiconductor device shown in FIG. 1 is completed.

As mentioned above, in the method of manufacturing a semiconductor device according to the present embodiment, the projected electrodes 3 and the pad electrodes 6 are superposed and a predetermined pressuring force is applied therebetween. Then, while keeping the projected electrodes 3 in an elastically deformed condition, ultrasonic vibration having a relatively small energy is applied to the projected electrodes 3 for a relatively long time. Thereby, the resin material and the inorganic filler can be removed from the superposed interface portion between the projected electrodes 3 and the pad electrodes 6, and the projected electrodes 3 and the pad electrodes 6 can be electrically coupled. Therefore, it is possible to decrease electrical resistance between the projected electrodes 3 and the pad electrodes 6. As a result, it is possible to fabricate a semiconductor device having stable electrical characteristics and improved reliability. In case the diameter of each electrode must be reduced to cope with needs for downsizing the semiconductor device and/or for increasing the number of the electrodes, electrical connection between the electrodes is conventionally liable to become unstable. Even in such case, in accordance with the manufacturing method of the present embodiment, it is possible to realize sure electrical coupling between the projected electrodes of the semiconductor pellet and the pad electrodes of the wiring substrate.

Also, in accordance with the method of manufacturing a semiconductor device according to the present embodiment, the inorganic filler 8 excluded from the space between the projected electrodes 3 and the pad electrodes 6 is distributed with a high concentration near and around the coupling portions between the projected electrodes 3 and the pad electrodes 6. That is, concentration or dispersion rate of the inorganic filler 8 in the resin material becomes larger in the portions near and around the coupling portions than in other portions of the resin material. Therefore, in the portion near and around the coupling portion between the projected electrodes 3 and the pad electrodes 6, passage of moisture therethrough is prevented by the inorganic filler 8. Therefore, it is possible to prevent moisture from entering into the coupling portions between the projected electrodes 3 and the pad electrodes 6. Thereby, it is possible to fabricate a semiconductor device having improved moisture resistance and improved reliability. Also, the inorganic filler 8 having a thermal expansion coefficient close to that of the projected electrodes 3 exists with high concentration near and around the coupling portions between the projected electrodes 3 and the pad electrodes 6. Therefore, it is possible to effectively mitigate a stress exerted on the coupling portions between the projected electrodes 3 and the pad electrodes 6 and caused by the temperature rise or fall. As a result, it is possible to fabricate a semiconductor device having an improved reliability of electrical coupling between the projected electrodes 3 and the pad electrodes 6.

In the above, the pressuring force per one projected electrode 3 of the semiconductor pellet 1 can be determined appropriately, within a range in which the projected electrodes can maintain elastically deformed condition, depending on the diameter, the shape and the like of the projected electrodes 3.

The output power of the ultrasonic vibration per one projected electrode is preferably in a range from 20 to 100 mW. In case the output power is smaller than 20 mW, even if the ultrasonic vibration is applied for a long time, it is impossible to exclude the resin material 7a and the inorganic filler 8 remaining in the superposed interface portion between the projected electrodes 3 and the pad electrodes 6. Therefore, electrical coupling between the projected electrodes 3 and the pad electrodes 6 becomes unstable. In case the output power of the ultrasonic vibration is larger than 100 mW, there is a possibility that the projected electrodes 3 deform inappropriately, that the projected electrodes 3 delaminate from the semiconductor substrate 2 of the semiconductor pellet 1, or that pad electrodes 6 delaminate from the wiring substrate 4. As a result thereof, there is a possibility that the electrical connection of the semiconductor device is damaged.

Further, the time of application of the ultrasonic vibration is preferably in a range from 0.1 to 5 seconds. In case it is shorter than 0.1 second, it is impossible to sufficiently exclude the resin material 7a and the inorganic filler 8 remaining in the superposed interface portion between the projected electrodes 3 and the pad electrodes 6. Also, even if it is longer than 5 seconds, the electrical connection between the projected electrodes 3 and the pad electrodes 6 is not improved any more.

In the above-mentioned embodiment, ultrasonic vibration is applied to the semiconductor pellet 1 to vibrate the projected electrodes 3 and thereby the resin material 7a near the projected electrodes 3 is vibrated. Alternatively, however, it is possible to vibrate the supporting table 9 by an ultrasonic wave, and to vibrate the resin material 7a relative to the projected electrodes 3 which are fixed.

In place of electrically coupling the projected electrodes 3 and the pad electrodes 6 by ultrasonic bonding, it is possible to electrically couple the projected electrodes 3 and the pad electrodes 6 by using thermo compression bonding. In such case, it is also possible, after vibrating the resin material 7a to lower viscosity of the resin material near the projected electrodes 3 and the pad electrodes 6, to press the projected electrodes 3 on the pad electrodes 6 and to apply heat to perform thermo compression bonding. It is also possible to use a combination of ultrasonic bonding and thermo compression bonding.

When thermosetting resin is used as the resin material 7a, it is preferable that the resin material 7a is heated to lower viscosity thereof, before applying ultrasonic vibration to the resin material 7a. Thereby, it is possible to cure the resin material 7a within a short time after the electrical coupling between the projected electrodes 3 and the pad electrodes 6 is completed.

When the diameter or size of each of the projected electrodes of electrode is reduced to cope with needs for downsizing the semiconductor device and/or for increasing the number of the electrodes, the area of each of the superposed interface portions between the electrodes becomes relatively small when compared with the size of the inorganic filler. Even in such case, in accordance with the present invention, it is possible to exclude the inorganic filler from the superposed interface portions between the projected electrodes and the pad electrodes sufficiently. Thereby, it is possible to make the effective conduction area of each projected electrode maximum and to keep electrical resistance between the projected electrode and the pad electrode minimum. Therefore, a semiconductor device having stable electrical characteristics can be realized.

Also, in the semiconductor device according to the present invention, concentration or dispersion rate of the inorganic filler around and near the outside portion of the interface portion between each of the projected electrodes and the corresponding one of the pad electrodes is larger than that of the inorganic filler in other portion of the resin material portion. That is, concentration of the resin material itself in the proximity of coupling portions between the projected electrodes and the pad electrodes is relatively small. Therefore, in the proximity of the coupling portions between the projected electrodes and the pad electrodes, penetration of moisture is inhibited by the inorganic filler and it is possible to avoid moisture from penetrating into the coupling portions between the projected electrodes and the pad electrodes. Thus, it is possible to improve moisture resistance and reliability of a semiconductor device. Also, since the inorganic filler having a thermal expansion coefficient close to that of the projected electrodes exists around and near the outside portions of the coupling portions between the projected electrodes and the pad electrodes with high concentration, it is possible to effectively mitigate the stress caused by the raise and fall of temperature at the coupling portion between the projected electrodes and the pad electrodes. Thereby, reliability of electrical connection between the projected electrodes and the pad electrodes can be improved.

Also, in the method of manufacturing a semiconductor device according to the present invention, vibration is applied to the projected electrodes or the pad electrodes while keeping the projected electrodes in an elastically deformed condition and thereby it becomes possible to effectively remove resin material and the inorganic filler from the superposed interface portions between the projected electrodes and the pad electrodes. Therefore, it is possible to fabricate a semiconductor device in which sure electrical coupling between the projected electrodes of the semiconductor pellet and the pad electrodes of the wiring substrate can be realized.

Also, in accordance with the method of manufacturing a semiconductor device according to the present invention, the inorganic filler excluded from the space between the projected electrodes and the pad electrodes is distributed with a high concentration near and around the coupling portions between the projected electrodes and the pad electrodes. That is, concentration of the inorganic filler in the resin material becomes larger in the portions near and around the coupling portions than in other portions of the resin material. Therefore, in the portion near and around the coupling portion between the projected electrodes and the pad electrodes, passage of moisture therethrough is prevented by the inorganic filler. Therefore, it is possible to prevent moisture from entering into the coupling portions between the projected electrodes and the pad electrodes. Thereby, it is possible to fabricate a semiconductor device having improved moisture resistance and improved reliability. Also, the inorganic filler having a thermal expansion coefficient close to that of the projected electrodes exists with high concentration near and around the coupling portions between the projected electrodes and the pad electrodes. Therefore, it is possible to effectively mitigate a stress exerted on the coupling portions between the projected electrodes and the pad electrodes and caused by the temperature rise or fall. As a result, it is possible to fabricate a semiconductor device having an improved reliability of electrical coupling between the projected electrodes and the pad electrodes.

In the foregoing specification, the invention has been described with reference to specific embodiments. However, one of ordinary skill in the art appreciates that various modifications and changes can be made without departing from the scope of the present invention as set forth in the claims below. Accordingly, the specification and figures are to be regarded in an illustrative sense rather than a restrictive sense, and all such modifications are to be included within the scope of the present invention. Therefore, it is intended that this invention encompasses all of the variations and modifications as fall within the scope of the appended claims.

What is claimed is:

1. A method of manufacturing a semiconductor device comprising:
preparing a semiconductor pellet having a plurality of projected electrodes;
preparing a wiring substrate having a plurality of pad electrodes;
applying liquid resin material including inorganic filler dispersed therein on said wiring substrate;
opposing said semiconductor pellet to said wiring substrate via said resin material, and electrically coupling said projected electrodes and said pad electrodes by superposing and pressing said projected electrodes onto said pad electrodes, said projected electrodes and said pad electrodes being electrically coupled while vibrating said resin material in the proximity of said projected electrodes and excluding said inorganic filler from superposed interface portions between said projected electrodes and said pad electrodes; and
curing said resin material to join said semiconductor pellet and said wiring substrate.

2. A method of manufacturing a semiconductor device as set forth in claim 1, wherein an end portion of each of said projected electrodes has a cross section which becomes smaller toward the tip portion thereof.

3. A method of manufacturing a semiconductor device as set forth in claim 1, wherein said resin material in the proximity of said projected electrodes is vibrated by applying ultrasonic vibration to said semiconductor pellet or to said wiring substrate.

4. A method of manufacturing a semiconductor device as set forth in claim 3, wherein in said opposing said semiconductor pellet to said wiring substrate via said resin material, and electrically coupling said projected electrodes and said pad electrodes by superposing and pressing said projected electrodes onto said pad electrodes, said projected electrodes are pressed onto said pad electrodes such that said projected electrodes are elastically deformed, and application of said ultrasonic vibration is started in a condition said projected electrodes are elastically deformed.

5. A method of manufacturing a semiconductor device as set forth in claim 4, wherein, by starting said application of said ultrasonic vibration in a condition said projected electrodes are elastically deformed, an area of contact of each of said projected electrodes with corresponding one of said pad electrodes rapidly enlarges.

6. A method of manufacturing a semiconductor device as set forth in claim 3, wherein an output of said ultrasonic vibration is 20-100 mW per one projected electrode.

7. A method of manufacturing a semiconductor device as set forth in claim 3, wherein an application time of said ultrasonic vibration is 0.1-5 seconds.

8. A method of manufacturing a semiconductor device as set forth in claim 3, wherein said projected electrodes and said pad electrodes are ultrasonic bonded.

9. A method of manufacturing a semiconductor device as set forth in claim 1, wherein in said in said opposing said semiconductor pellet to said wiring substrate via said resin material, and electrically coupling said projected electrodes and said pad electrodes by superposing and pressing said projected electrodes onto said pad electrodes, said projected electrodes and said pad electrodes are thermo compression bonded by pressing said projected electrodes onto said pad electrodes while heating said semiconductor pellet.

10. A method of manufacturing a semiconductor device as set forth in claim 1, wherein, before vibrating said resin material in the proximity of said projected electrodes, said resin material is heated to lower viscosity of said resin material.

11. A method of manufacturing a semiconductor device as set forth in claim 1, wherein said inorganic filler comprises minute powder of alumina or silica.

12. A semiconductor device comprising:
a wiring substrate having a plurality of pad electrodes;
a semiconductor pellet having a plurality of projected electrodes and opposed to said wiring substrate, said projected electrodes of said semiconductor pellet being electrically coupled with said pad electrodes of said wiring substrate, respectively; and
a resin material portion filling a space between said semiconductor pellet and said wiring substrate and joining said semiconductor pellet and said wiring substrate, said resin material including inorganic filler dispersed therein;
wherein said inorganic filler hardly exists in superposed interface portions between said projected electrodes and said pad electrodes, and a dispersion rate of said inorganic filler in said resin material is larger in portions near and around said superposed interface portions than in other portions of said resin material.

13. A method of manufacturing a semiconductor device comprising:
preparing a semiconductor pellet having a plurality of projected electrodes;
preparing a wiring substrate having a plurality of pad electrodes;
applying liquid resin material including inorganic filler dispersed therein on said wiring substrate;
opposing said semiconductor pellet to said wiring substrate via said resin material, and superposing and pressing said projected electrodes onto said pad electrodes, said projected electrodes being pressed onto said pad electrodes such that said projected electrodes are elastically deformed;
applying ultrasonic vibration to said semiconductor pellet and/or said wiring substrate in a condition said projected electrodes are pressed onto said pad electrodes such that said projected electrodes are elastically deformed, and electrically coupling said projected electrodes and said pad electrodes; and
curing said resin material to join said semiconductor pellet and said wiring substrate.

14. A method of manufacturing a semiconductor device as set forth in claim 13, wherein an end portion of each of said projected electrodes has a cross section which becomes smaller toward the tip portion thereof.

15. A method of manufacturing a semiconductor device as set forth in claim 13, wherein, in said applying ultrasonic vibration to said semiconductor pellet and/or said wiring substrate in a condition said projected electrodes are pressed onto said pad electrodes such that said projected electrodes are elastically deformed, and electrically coupling said projected electrodes and said pad electrodes, said projected electrodes expand in radial directions and are compressed in axial direction by applying said ultrasonic vibration to said semiconductor pellet, said projected electrodes and said pad electrodes being electrically coupled while excluding said inorganic filler from superposed interface portions between said projected electrodes and said pad electrodes.

16. A method of manufacturing a semiconductor device as set forth in claim 13, wherein, in said applying ultrasonic vibration to said semiconductor pellet and/or said wiring substrate in a condition said projected electrodes are pressed onto said pad electrodes such that said projected electrodes are elastically deformed, and electrically coupling said projected electrodes and said pad electrodes, an area of contact of each of said projected electrodes with corresponding one of said pad electrodes is rapidly enlarged by applying said ultrasonic vibration to said semiconductor pellet, said projected electrodes and said pad electrodes being electrically coupled while excluding said inorganic filler from superposed interface portions between said projected electrodes and said pad electrodes.

17. A method of manufacturing a semiconductor device as set forth in claim 13, wherein an output of said ultrasonic vibration is 20-100 mW per one projected electrode.

18. A method of manufacturing a semiconductor device as set forth in claim 13, wherein an application time of said ultrasonic vibration is 0.1-5 seconds.

19. A method of manufacturing a semiconductor device as set forth in claim 13, wherein, before applying said ultrasonic vibration, said resin material is heated to lower viscosity of said resin material.

20. A method of manufacturing a semiconductor device as set forth in claim 13, wherein said inorganic filler comprises minute powder of alumina or silica.
